(19) United States
(12) Patent Application Publication
(10) Pub. No.: US 2018/0164474 A1
(43) Pub. Date: Jun. 14, 2018

(54) PROJECTION OBJECTIVE FOR MICROLITHOGRAPHY

(71) Applicant: Carl Zeiss SMT GmbH, Oberkochen (DE)

(72) Inventors: Daniel Kraehmer, Essingen (DE); Aurelian Dodoc, Heidenheim (DE); Hans-Juergen Mann, Oberkochen (DE); Toralf Gruner, Aalen-Hofen (DE)

(21) Appl. No.: 15/894,293

(22) Filed: Feb. 12, 2018

Related U.S. Application Data
(62) Division of application No. 12/723,456, filed on Mar. 12, 2010.
Application No. 12/723,456 is a continuation of application No. PCT/EP2008/007807, filed on Sep. 18, 2008.
(60) Provisional application No. 60/974,171, filed on Sep. 21, 2007.

(30) Foreign Application Priority Data
Sep. 21, 2007 (DE) 10 2007 046 398.9

(51) Int. Cl. G02B 5/00; G03F 7/20; G02B 27/00; G02B 17/06

(52) U.S. Cl. CPC G02B 5/003; G03F 7/70233; G02B 27/0018; G02B 17/0657; G02B 5/005

(57) ABSTRACT

A projection objective with obscurated pupil for microlithography has a first optical surface, which has a first region provided for application of useful light, and at least one second optical surface, which has a second region provided for application of useful light. A beam envelope of the useful light extends between the first region and the second region. At least one tube open on the input side and on the output side in the light propagation direction severs to screen scattered light. The at least one tube is between the first optical surface and the second optical surface. The wall of the tube is opaque in the wavelength range of the useful light. The tube extends in the propagation direction of the useful light over at least a partial length of the beam envelope and circumferentially surrounds the beam envelope.

### CROSS-REFERENCE TO RELATED APPLICATIONS

This application is a continuation of, and claims benefit under 35 USC 120 to, international application PCT/EP2008/007807, filed Sep. 18, 2008, which claims benefit of German Application No. 10 2007 046 398.9, filed Sep. 21, 2007 and U.S. Ser. No. 60/974,171, filed Sep. 21, 2007. International application PCT/EP2008/007807 is hereby incorporated by reference in its entirety.

### FIELD

The disclosure relates to a projection objective for microlithography with an obscurated pupil. The projection objective includes a first optical surface, which has a first region provided for application of useful light. The projection objective also includes at least one second optical surface, which has a second region provided for application of useful light. A beam envelope of the useful light extends between the first region and the second region during the operation of the projection objective.

### BACKGROUND

A projection objective for microlithography is known from the document WO 2006/069725 A1.

Projection objectives are used in microlithography in projection exposure apparatuses for the production of semiconductor components and other finely structured components. In this case, the projection objectives serve to project patterns of photomasks or optical reticles, also referred to generally as masks or reticles, onto an object coated with a light-sensitive layer with maximum resolution on a reduced scale.

In this case, in order to produce ever finer structures it is often desirable to increase the image-side numerical aperture (NA) of the projection objective and to use ever shorter wavelengths. In some cases, wavelengths of less than 20 nm, that is to say in the extreme ultraviolet (EUV), are used.

In the EUV wavelength range, only materials whose transparency is not very adequate may be available for the production of optical components. Accordingly, in general, projection objectives for EUV lithography have exclusively reflective optical elements. Such projection objectives are correspondingly referred to as catoptric.

WO 2006/069725 proposes, in order to obtain a high image-side numerical aperture, obscurating the pupil of the projection objective by providing one or a plurality of the optical surfaces, mirrors in that case, with through holes through which the useful light passes. In that case, the through holes lie approximately on the optical axis.

In the case of such obscurated projection objectives, it can be important for the imaging quality that the useful light is applied to all the optical surfaces of the projection objective which are provided for application of the useful light in the correct order and without omitting one or more of the optical surfaces before it passes into the image plane.

Precisely in the case of obscurated projection objectives, however, it can happen that scattered light passes through the through holes in the optical surfaces directly into the image plane without previously impinging on all the regions of the optical surfaces which are provided for application of useful light.

Within the meaning of the present disclosure, “scattered light” is understood to be not only that light which arises as a result of undesirable reflections at the optical surfaces, but also so-called over-apertured light, that is to say those light beams which have a larger aperture than the system aperture.

Within the meaning of the present disclosure, “beam envelope” of the useful light should be understood to be the totality of the marginal rays of the useful light bundle or in other words the envelope of the useful light beam.

The reason why scattered light passes through the through holes in the optical surfaces directly into the image plane whilst omitting specific optical surfaces may be due to the fact that the scattered light passes through the through holes at an angle of incidence that deviates from the angular range which the useful light exhibits upon passing through the through holes.

### SUMMARY

In some embodiments, the disclosure provides a projection objective with an obscurated pupil for microlithography in which the imaging properties are improved by more effective suppression of scattered light.

In certain embodiments, at least one tube open on the input side and on the output side in the light propagation direction and serving for screening scattered light is arranged between the first optical surface and the second optical surface. The tube extends in the propagation direction of the useful light over at least a partial length of the beam envelope and circumferentially surrounding the beam envelope.

In a projection objective, the beam envelope of the useful light between two optical surfaces is enclosed by a tube which is circumferentially closed but open at the ends. The fact that the beam envelope is enclosed by the at least one tube means that the useful light can pass undisturbed through the tube, whereas scattered light, that is to say that light which arises as a result of undesirable reflections, or over-aperture light, having a different propagation direction with respect to the beam envelope of the useful light, is effectively screened by the tube. For this purpose, the at least one tube can be absorbent on the inside and/or on the outside.

In one exemplary configuration, the beam envelope of the useful light between the first optical surface and the second optical surface is a first beam envelope and is overlapped by a second beam envelope of the useful light over a partial length of the first beam envelope. The tube extends over at least a partial length of the overlap-free partial region of the first beam envelope.

In this case, it is advantageous that the at least one tube ensures the undisturbed propagation of the useful light in the overlap region of the two beam envelopes.

In this case, it is desirable for the tube to extend over the entire length of the overlap-free partial region of the first beam envelope.

In this case, it is advantageous that the scattered light suppression by the at least one tube is particularly effective because the beam envelope of the useful light is enclosed over the maximum possible length in the light propagation direction.

It generally holds true that the at least one tube ensures an optimum scattered light suppression if it surrounds the beam envelope of the useful light between the two optical surfaces over at least 50% of the beam envelope length, such as over the entire beam envelope length.

In a further exemplary configuration, the tube surrounds the beam envelope at a minimal distance, for example at a distance of less than 2 mm (e.g., less than 1 mm, less than 0.2 mm) but contactlessly.

If the tube surrounds the beam envelope contactlessly, this prevents the tube from disturbing the propagation of the useful light. The smaller the distance between the tube and the beam envelope of the useful light, the more effective the scattered light screening by the tube is, too, because even that scattered light whose propagation direction deviates only slightly from that of the beam envelope is effectively prevented from propagating by the tube.

In a further exemplary configuration, an intermediate image is generated between the first optical surface and the second optical surface, and the tube is arranged at least in proximity to the intermediate image.

The beam envelope of the useful light has the smallest circumference in the region of an intermediate image, such that the region of the intermediate image is particularly well suited to the arrangement of the at least one tube because the at least one tube can likewise be formed with a small circumference, such that the at least one tube does not occupy a large structural space within the projection objective.

In a further exemplary configuration, the geometrical shape of the interior of the tube is adapted to the shape of the beam envelope.

This measure is advantageous particularly in conjunction with one of the measures mentioned above according to which the tube surrounds the beam envelope of the useful light at a minimal distance, because, as a result of the adaptation of the geometrical shape of the interior of the tube to the shape of the beam envelope, the minimal distance is complied with over the entire circumference of the beam envelope and over the entire length over which the tube extends.

In one exemplary practical configuration, if the beam envelope is truncated cone shaped, the tube is likewise formed in truncated-cone-shaped fashion.

If the beam envelope is double truncated cone shaped, the tube can be formed in double-truncated-cone-shaped fashion or at least two truncated-cone-shaped tubes surround the beam envelope.

A double-truncated-cone-shaped form of the beam envelope of the useful light is advantageous in particular at an intermediate image since the beam envelope of the useful light both upstream of the intermediate image and downstream of the intermediate image is circumferentially enclosed by the one double-truncated-cone-shaped tube or the two truncated-cone-shaped tubes.

In a further exemplary configuration, a third optical surface provided with a through hole is arranged between the first optical surface and the second optical surface. The through hole serves for the passage of the useful light, and the tube is arranged in or in the region of the through hole.

This measure has the further advantage that the propagation of scattered light through the through hole in an optical surface can be effectively suppressed, while the useful light passes unimpeded through the through hole, to be precise through the tube. The present disclosure can advantageously be applied to catoptric projection objectives with an obscurated pupil, in particular to projection objectives for EUV microlithography.

However, the present disclosure is not restricted to catoptric projection objectives in the EUV range, but rather can also be used for projection objectives used in the longer-wavelength range.

### BRIEF DESCRIPTION OF THE DRAWINGS

Further advantages and features will become apparent from the description below and the accompanying drawing. It goes without saying that the features mentioned above and those explained below can be used not only in the combination respectively specified, but also in other combinations or by themselves, without departing from the scope of the present dislcosure. Exemplary embodiments of the disclosure are illustrated in the drawing and are described below with reference to the drawing, in which:

FIG. 1 shows a first exemplary embodiment of a projection objective for microlithography with an obscurated pupil;

FIG. 2 shows a tube for screening scattered light, which can be used in the projection objective in FIG. 1;

FIG. 3 shows a further exemplary embodiment of a projection objective for microlithography with an obscurated pupil;

FIG. 4 shows a tube for use in the projection objective in FIG. 3; and

FIG. 5 shows yet another exemplary embodiment of a projection objective for microlithography with an obscurated pupil.

### DETAILED DESCRIPTION

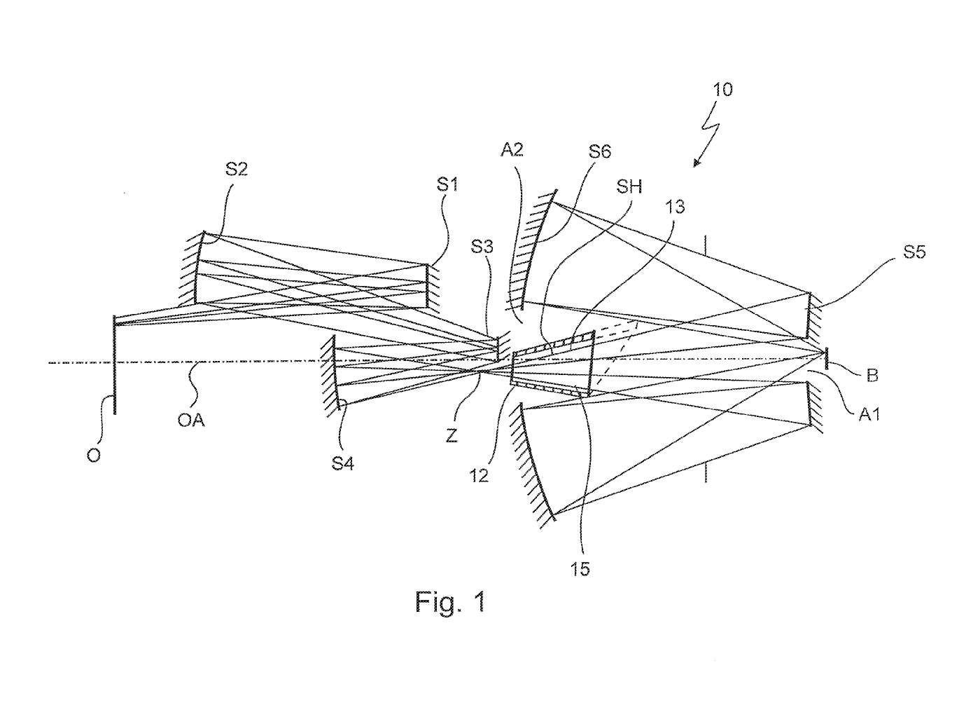

FIG. 1 illustrates a projection objective for microlithography 10 with an obscurated pupil. The projection objective 10 has six optical surfaces S1, S2, S3, S4, S5 and S6 between an object plane O and an image plane B as seen in the light propagation direction. The optical surfaces S1 to S6 are all mirrors, such that the projection objective 10 is a catoptric projection objective.

An optical axis of the projection objective 10 is designated by OA.

The optical surfaces S1 to S6 each have a region provided for application of useful light. FIG. 1 illustrates the optical surfaces S1 to S6 exclusively with their regions provided for application of useful light.

FIG. 1 also illustrates the beam path of the useful light. The beam envelope SH of the useful light is illustrated, that is to say the beam cone formed by the totality of the marginal rays of the useful light beam bundle, of which two marginal rays 13 and 15 are illustrated.

An intermediate image Z is furthermore situated between the optical surfaces S4 and S5. On account of the intermediate image Z, the beam envelope SH of the useful light between the optical surfaces S4 and S5 has the shape of a double cone or double truncated cone, the circumferentially narrowest location of which lies in the intermediate image Z.

The optical surface S5 has a through hole A1 and the optical surface S6 has a through hole A2, through which the useful light passes in each case. The useful light passes through the through hole A2 on the way from the optical surface S4 to the optical surface S5, and the useful light passes through the through hole A1 proceeding from the optical surface S6 to the image plane B.

In order, then, to prevent scattered light—which is generated for example at one of the optical surfaces S1, S2, S3 or S4 or which includes over-aperture light—from passing through the through hole A2 and through the through hole A1 directly into the image plane B, the beam envelope SH of the useful light between the optical surfaces S4 and S5 is surrounded by a tube 12 over a partial length of the beam envelope SH, the tube screening scattered light or preventing it from propagating.

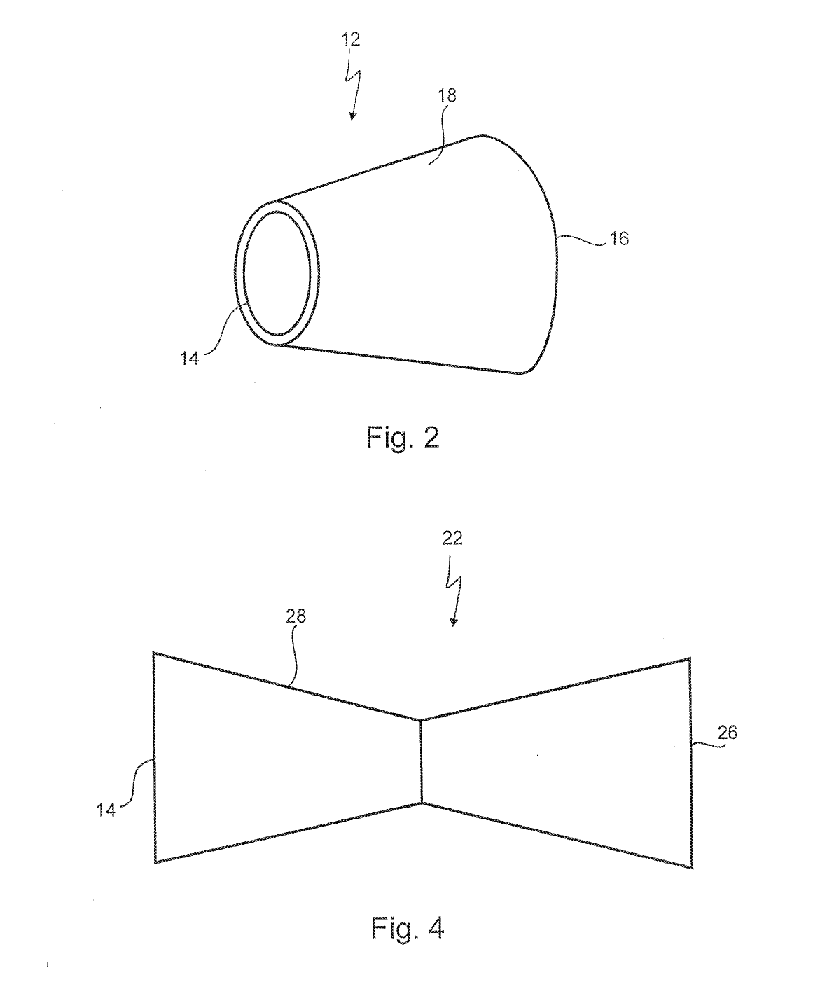

The tube 12 is illustrated by itself in FIG. 2. The tube 12 is open at an input side 14 and at an output side 16, that is to say has no material there, not even a material that is transparent to the useful light.

The tube 12 has a circumferential wall 18, which, by contrast, is fully circumferentially closed and optionally absorbent on the inside and/or on the outside.

In accordance with FIG. 1, the tube 12 surrounds the beam envelope of the useful light between the optical surfaces S4 and S5 only over a partial length, to be precise in the region in which the beam envelope of the useful light does not overlap the beam envelope of the useful light between the optical surfaces S3 and S4 or the beam envelope between the optical surfaces S5 and S6 or the beam envelope between the optical surface S6 and the image plane.

For better utilization of the overlap-free region of the beam envelopes, the tube 12 can also have a shape such as is supplemented by interrupted lines in FIG. 1.

In this case, therefore, the tube 12 extends over the entire length of the beam envelope of the useful light between the optical surfaces S4 and S5 in which the beam envelope does not overlap the beam envelopes between the optical surfaces S3 and S4, or S5 and S6, or S6 and the image plane.

In the exemplary embodiment in accordance with FIGS. 1 and 2, the tube 12 has the shape of a truncated cone, in which case the end sides of the truncated cone need not necessarily run parallel to one another, as is shown by interrupted lines from the illustration in FIG. 1. Within the meaning of the present disclosure, “truncated cone shaped” encompasses all geometries in which the tube widens rectilinearly in diameter from one end to the other, in which case the base areas of the tube can be any closed one-dimensional curves, that is to say including non-circular curves.

The tube 12 surrounds the beam envelope of the useful light between the optical surfaces S4 and S5 at as minimal a distance as possible, but without touching the beam envelope SH.

In the projection objective 10, the tube 12 is arranged in the vicinity of the intermediate image Z, but cannot reach as far as the intermediate image Z for structural reasons owing to the optical surface S3.

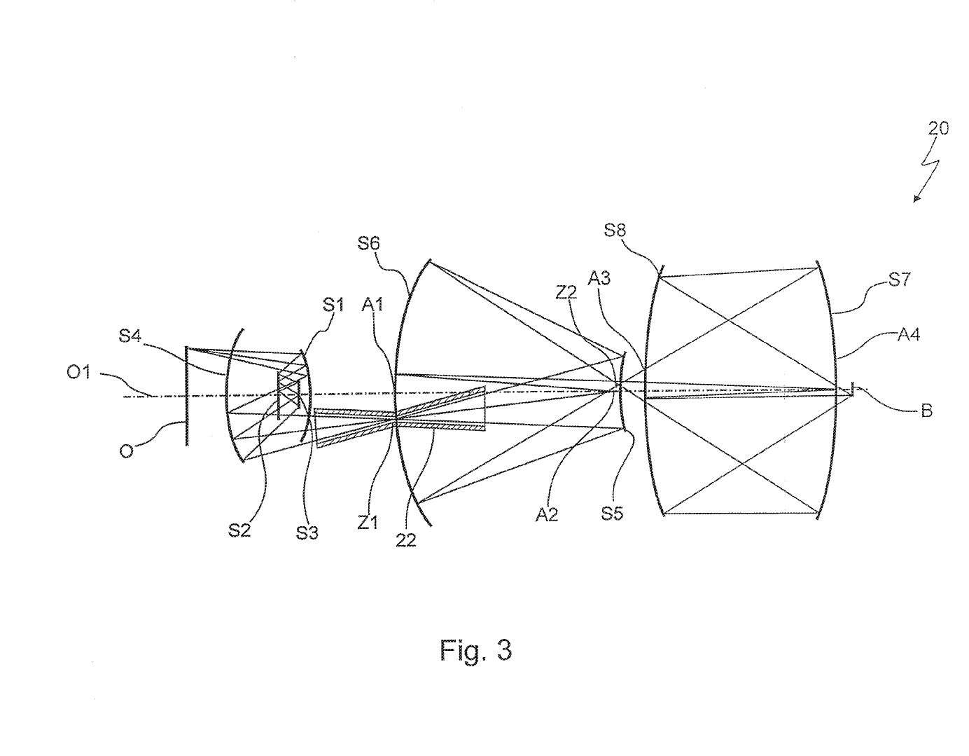

FIG. 3 illustrates a further exemplary embodiment of a projection objective for microlithography 20 with an obscurated pupil.

The projection objective 20 has eight optical surfaces S1 to S8 between an object plane O and an image plane B in the sequence of light propagation, the optical surface S6 having a through hole A1, the optical surface S5 having a through hole A2, the optical surface S8 having a through hole A3 and the optical surface S7 having a through hole A4.

The optical surfaces S1 to S8 are all realized by mirrors, such that the projection objective 20 is a catoptric projection objective. In contrast to the illustration in accordance with FIG. 1, the illustration in FIG. 3 illustrates the optical surfaces S1 to S8 symmetrically with respect to the optical axis OA, that region of each optical surface to which the useful light is applied in each case resulting from the beam envelope of the useful light depicted in FIG. 3 at each optical surface S1 to S8. In contrast to FIG. 1, the obscurated partial region of the beam bundle is not illustrated in FIG. 3.

The arrangement of the optical surfaces S1 to S8 generates a first intermediate image at Z1 and a second intermediate image at Z2.

A tube 22 is arranged between the optical surfaces S4 and S5. The tube circumferentially surrounds the beam envelope of the useful light between the optical surfaces S4 and S5. The tube 22 extends over a partial length of the beam envelope of the useful light between the optical surfaces S4 and S5 in which the useful light does not overlap the useful light between the optical surfaces S3 and S4 and S5 and S6 and between the optical surface S6 and the image plane.

The tube 22 surrounds the beam envelope of the useful light in the intermediate image Z1 and on both sides of the intermediate image Z1, as revealed in FIG. 3.

Furthermore, the tube 22 passes through the through hole A1 in the optical surface S6, which makes it possible for the tube 22 to be mechanically fixed in particular to the through hole A1.

Since the beam envelope of the useful light on both sides of the intermediate image Z1 has the shape of a double truncated cone, the tube 22 is advantageously likewise formed as a double truncated cone.

FIG. 4 illustrates the tube 22 by itself.

Like the tube 12, the tube 22 is open at its longitudinal ends 24 and 26 and has a wall 28 that is opaque to light in the wavelength range of interest and is optionally absorbent on the inside and/or on the outside.

Instead of the double-truncated-cone-shaped tube 22, it is also possible to arrange two tubes in accordance with FIG. 2 in the place of the tube 22 in the projection objective 20 in FIG. 3, these tubes then correspondingly being arranged with their narrow ends facing one another.

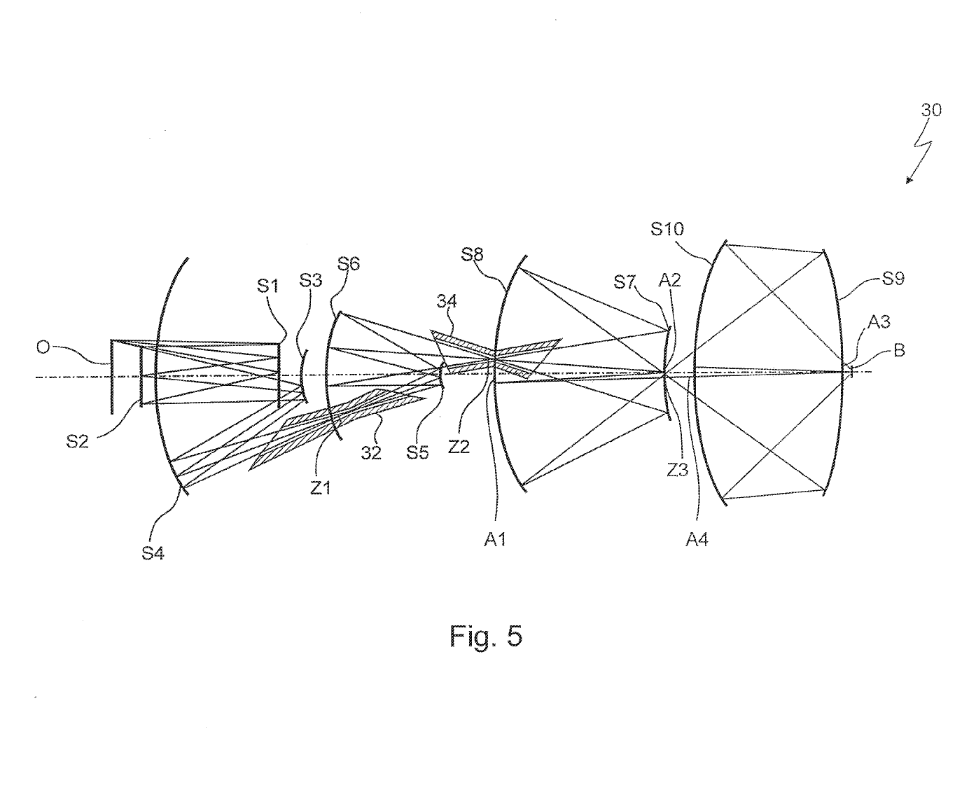

FIG. 5 illustrates yet another exemplary embodiment of a projection objective for microlithography 30 with an obscurated pupil.

The projection objective 30 has a total of ten optical surfaces S1 to S10 between an object plane O and an image plane B, the optical surfaces being realized as mirrors, such that the projection objective 30 is catoptric.

The projection objective 30 generates three intermediate images at Z1, Z2 and Z3. As in FIG. 3, the obscurated partial region of the beam bundle is not illustrated in FIG. 5.

In the projection objective 30, the beam envelope of the useful light in the region of the intermediate image Z1 between the optical surfaces S4 and S5 is surrounded by a tube 32 over a partial length that is free of overlaps with adjacent beam envelopes of the useful light, and, in addition, the beam envelope of the useful light between the optical surfaces S6 and S7 is surrounded by a second tube 34.

The tubes 32 and 34 essentially correspond to the tube 22 in accordance with the exemplary embodiment in FIG. 3.

In the region of the intermediate image Z2, the optical surface S8 has a through hole A1, in which the tube 34 is advantageously arranged. Further through holes are situated at the optical surfaces S7, S9 and S10, the through holes being designated by A2, A3 and A4.

The projection objectives 10, 20 and 30 described above are suitable in particular for use in EUV lithography.

1.-20. (canceled)

21. An objective configured so that, during use, useful light can propagate through the objective along a light propagation direction, the objective comprising:
a first optical surface having a first region that interacts with the useful light during use of the objective;
a second optical surface having a second region that interacts with the useful light during use of the objective;
a third optical surface comprising a reflective surface and a through hole; and
a tube between the first and second optical surfaces along the light propagation direction, wherein:
during use of the objective, a beam envelope of the useful light extends between the first and second regions;
during use of the objective, an intermediate image is generated between the first and second optical surfaces;
the intermediate image is in the through hole;
the tube is arranged at least in proximity to the intermediate image;
the tube is open on an input side in the light propagation direction;
the tube is open on an output side in the light propagation direction;
the tube screens scattered light during use of the objective;
the tube has a wall that is opaque in a wavelength range of the useful light;
the tube extends in the propagation direction of the useful light over at least a partial length of the beam envelope;
the tube extends circumferentially surrounding the beam envelope;
the reflective surface comprises first and second portions;
the through hole is between the first and second portions of the reflective surface;
during use of the objective, the useful light is reflected from the first and second portions of the reflective surface; and
the objective is microlithography objective.

22. The objective of claim 21, wherein the beam envelope between the first and second optical surfaces is a first beam envelope, the first beam envelope is overlapped by a second beam envelope of the useful light over a partial length of the first beam envelope so that a portion of the first beam envelope does not overlap with the second beam envelope, and the tube extends over at least part the portion of the first beam envelope that does not overlap with the second beam envelope.

23. The objective of claim 22, wherein the tube extends over an entire length of the portion of the first beam envelope that does not overlap with the second beam envelope.

24. The objective of claim 21, wherein the tube contactlessly circumferentially surrounds the beam envelope.

25. The objective of claim 24, wherein a distance between the tube and the beam envelope is less than 2 mm.

26. The objective of claim 24, wherein a distance between the tube and the beam envelope is less than 1 mm.

27. The objective of claim 24, wherein a distance between the tube and the beam envelope is less than 0.2 mm.

28. The objective of claim 21, wherein the geometrical shape of an interior of the tube is adapted to a shape of the beam envelope.

29. The objective of claim 28, wherein the tube is truncated-cone-shaped.

30. The objective of claim 21, wherein the objective is a catoptric objective.

31. The objective of claim 30, wherein the objective is configured to be used for EUV microlithography.

32. The objective of claim 21, wherein the objective is configured to be used for EUV microlithography.

33. The objective of claim 21, wherein the input side of the tube is upstream of the through hole in the light propagation direction, and the output side of the tube is downstream of the though hole in the light propagation direction.

34. The objective of claim 21, wherein the tube is in the through hole.

35. An apparatus, comprising:
a projection objective being configured so that, during use of the apparatus, useful light can propagate through the projection objective along a light propagation direction, the projection objective comprising:
a first optical surface having a first region that interacts with the useful light during use of the apparatus;
a second optical surface having a second region that interacts with the useful light during use of the apparatus;
a third optical surface comprising a reflective surface and a through hole; and
a tube between the first and second optical surfaces along the light propagation direction,
wherein:
the apparatus is a microlithography projection exposure apparatus;
during use of the apparatus, a beam envelope of the useful light extends between the first and second regions;
during use of the objective, an intermediate image is generated between the first and second optical surfaces;
the intermediate image is in the through hole;
the tube is arranged at least in proximity to the intermediate image;
the tube is open on an input side in the light propagation direction;
the tube is open on an output side in the light propagation direction;
the tube screens scattered light during use of the apparatus;
the tube has a wall that is opaque in a wavelength range of the useful light;
the tube extends in the propagation direction of the useful light over at least a partial length of the beam envelope;
the tube extends circumferentially surrounding the beam envelope;
the reflective surface comprises first and second portions;
the through hole is between the first and second portions of the reflective surface; and
during use of the objective, the useful light is reflected from the first and second portions of the reflective surface.

36. The apparatus of claim 35, wherein the projection objective is a catoptric projection objective.

37. The apparatus of claim 36, wherein the apparatus is an EUV microlithography apparatus.

38. The apparatus of claim 35, wherein the tube is in the through hole.

39. A method, comprising:
using the apparatus of claim 35 to produce semiconductor components.

40. An objective configured so that, during use, useful light can propagate through the objective along a light propagation direction, the objective comprising:
a first optical surface having a first region that interacts with the useful light during use of the objective;
a second optical surface having a second region that interacts with the useful light during use of the objective;
a third optical surface comprising a reflective surface and a through hole, the reflective surface comprising first and second portions and a through hole between the first and second portions, the first and second portions of the reflective surface interacting with the useful light during use of the objective; and
a tube between the first and second optical surfaces along the light propagation direction, the tube having first and second openings,
wherein:
during use of the objective:
a beam envelope of the useful light extends between the first and second regions; and
an intermediate image is generated between the first and second optical surfaces so that the intermediate image is in the through hole and so that the tube is arranged at least in proximity to the intermediate image;
the tube extends in the propagation direction of the useful light over at least a partial length of the beam envelope so that the tube circumferentially surrounds the partial length of the beam envelope and useful light passes through the tube between the first and second openings; and
the objective is microlithography objective.
